(19) United States
(12) Patent Application Publication
(10) Pub. No.: US 2025/0366258 A1
(43) Pub. Date: Nov. 27, 2025

(54) METHOD FOR MANUFACTURING HIGH-OUTPUT ULTRA-VIOLET(UV) LED WITH THIN-FILM CHIP STRUCTURE THROUGH HOT SELF-SPLIT PROCESS

(71) Applicant: WAVELORD CO., LTD., Gyeonggi-do (KR)

(72) Inventors: June O SONG, Gyeonggi-do (KR); Jihyung MOON, Gyeonggi-do (KR); Younghun HAN, Gyeonggi-do (KR)

(21) Appl. No.: 19/219,193

(22) Filed: May 27, 2025

(30) Foreign Application Priority Data
May 27, 2024 (KR) 10-2024-0068674
Aug. 27, 2024 (KR) 10-2024-0114702

(51) Int. Cl. H10H 20/01

(52) U.S. Cl. CPC H10H 20/01335

(57) ABSTRACT

The present disclosure provides a method comprising: sequentially forming a buffer layer and an emission layer on a growth substrate made of SiC; forming an n-ohmic layer and/or a p-ohmic layer on the emission layer; irradiating a laser into the inside of the growth substrate to form a modified layer parallel to a growth surface of the growth substrate; bonding a support substrate to one of the n-ohmic layer and the p-ohmic layer formed by the first fabrication process; separating the growth substrate with the modified layer as a boundary, and leaving a seed region in the emission layer; removing the seed region and the buffer layer together to expose the emission layer, or removing only the seed region to expose the buffer layer; and forming a device structure including an electrode electrically connected to the light-emitting layer.

### CROSS-REFERENCE TO RELATED APPLICATIONS

This application claims priority to Korean Patent Application Nos. 10-2024-0068674, filed on May 27, 2024 and 10-2024-0114702, filed on Aug. 27, 2024. The entire disclosure of the applications identified in this paragraph is incorporated herein by reference.

### FIELD

The present invention relates to a method for manufacturing a high-power ultraviolet (UV) light-emitting device having a thin-film chip structure through a hot self-split process, and more particularly, to a method for manufacturing a thin-film chip structure UV light-emitting device capable of using an expensive SiC substrate as a consumable growth substrate with high cost-effectiveness and emitting deep ultraviolet rays in a wavelength band of 280 nm or less at high power.

### BACKGROUND

Ultraviolet light emitters are generally composed of a P-I-N (P-type semiconductor/Insulator/N-type semiconductor) structure as an active layer based on AlN & AlGaN. However, due to relatively high electrical resistance, they have the disadvantages of generating a lot of heat during operation and having a short lifespan.

In order to solve these problems and expand the application range of ultraviolet light-emitting devices, improvements in performance (improved optical power output, reduced operating voltage) and reliability are necessary.

In the case of deep ultraviolet light-emitting devices with a wavelength band of 280 nm or less, the main products currently under development and mass production are devices with low power or middle power of less than 100 mW at a current of less than 350 mA, and a flip chip structure with sapphire with a thickness of 200 μm or more is typical.

Conventional high-power blue, green and near-ultraviolet LED devices are thin-film chip structures that consist only of epitaxial thin films formed on a high-heat dissipation support substrate by separately removing the sapphire growth substrate. A representative example is the vertical chip structure.

However, it is difficult to find a deep ultraviolet light-emitting device with a light output performance of more than 100 mW in the market that has a thin film chip structure designed and manufactured on another support substrate after the initial growth substrate has been removed.

Deep ultraviolet light emitting devices with a wavelength band of 280 nm or less are used for industrial curing and exposure equipment, medical devices for skin and dental treatment, surgical medical devices, sterilization of various microorganisms and viruses, and water treatment, depending on the wavelength band. Since most of them are used in a direct irradiation manner, a thin film chip structure for high output performance is essential.

Therefore, it is essential to secure process technology for deep ultraviolet light emitting devices with a wavelength band of 280 nm or less to achieve optical power output of 100 mW or more by applying high current of 350 mA or more during operation, and to apply high heat dissipation technology for stable reliability and long life of 1,000 hrs or more.

However, in order to secure the above-mentioned technology, the following major problems must be solved.

First, when growing the active layer (P-I-N) structure of a deep UV light-emitting device on a sapphire growth substrate, a group III nitride (AlGalnN) layer (sacrificial separation layer) must first be formed to separate the sapphire growth substrate through the LLO (Laser Lift Off) process. However, it is difficult to grow a high-quality deep UV LED epitaxy active layer (P-I-N) structure on the sacrificial separation layer.

Second, in the case of a deep UV light-emitting device composed of AIN and Al-rich AlxGa1−xN (x>0.5), vertical current injection and horizontal current spreading are not good. Therefore, it is difficult to apply a high current of 350 mA or more and to manufacture a large-area chip.

Third, due to the absence of a metal electrode material capable of ohmic contact with the P-type semiconductor, the light extraction efficiency is low and the operating voltage is high, generating a large amount of heat.

Fourth, when growing the epitaxial structure of a deep ultraviolet light-emitting device composed of Al-rich AlGaN on a sapphire growth substrate, there are structural problems such as microcracks due to the high crystal defect density and large residual stress inside the epitaxy.

In particular, the epitaxial structure of an Al-rich AlGaN deep ultraviolet light-emitting device grown on a sapphire growth substrate contains many regions with an abnormal mixed polarity in which nitrogen polarity (N-polarity) is mixed in addition to the ideal metal (Aluminum, Gallium) polarity (Al-& Ga-polarity). This mixed polarity is known to be the source of a mechanism that causes fatal defects when high current (high power) is applied to the site of an aggregate of defects centered on screw dislocations.

As a solution to these problems, a technology using Si-polar SiC (4H, 6H) substrates as growth substrates is known.

However, in this case, there is a problem that expensive SiC substrates must be used as consumable materials, and even if the SiC substrate is not removed, the problem occurs that ultraviolet rays below 280 nm are absorbed due to the low energy band gap (3.2 eV, 380 nm) of SiC.

Therefore, there is an urgent need for a new idea for a method of manufacturing a high-output ultraviolet light-emitting device with a thin-film chip structure that is cost-effective while using expensive SiC substrates as consumable growth substrates.

### SUMMARY

### Technical Problem

The present invention provides a method for manufacturing an ultraviolet light emitting device having a thin-film chip structure capable of emitting deep ultraviolet rays in a wavelength band of 280 nm or less with high output and capable of using an expensive SiC substrate as a consumable growth substrate with high cost-effectiveness.

### Technical Solution

Embodiments according to the present invention provide a method for manufacturing a high-power ultraviolet light-emitting device having a thin-film chip structure through a hot self-split process comprising: an epitaxial growth step of sequentially forming a buffer layer and an emission layer on a growth substrate made of SiC (silicon carbide); a first fab process step of forming an n-ohmic layer and/or a p-ohmic layer on the emission layer; a growth substrate modification step of irradiating a laser into the inside of the growth substrate to form a modified layer parallel to a growth surface of the growth substrate; a support substrate bonding step of bonding a support substrate to one of the n-ohmic layer and the p-ohmic layer formed by the first fabrication process; a growth substrate separation step of separating the growth substrate with the modified layer as a boundary, and leaving a seed region, which is a part of the growth substrate, in the emission layer; a seed region removal step of removing the seed region and the buffer layer together to expose the emission layer, or removing only the seed region to expose the buffer layer; and a second fab process step of forming a device structure including an electrode electrically connected to the light-emitting layer.

In embodiments according to the present invention, the growth substrate separation step is performed such that the growth substrate is separated with the modified layer as a boundary due to thermal stress or mechanical stress formed in the modified layer as a result of the support substrate bonding.

In embodiments according to the present invention, the growth substrate separated from the light-emitting layer by the growth substrate separation step is reused for the growth of a new buffer layer and light-emitting layer.

In embodiments according to the present invention, the support substrate bonding step bonds an electrically conductive device bonding layer formed on one surface of the light-emitting layer and an electrically conductive substrate bonding layer formed on the support substrate.

In embodiments according to the present invention, the light-emitting layer comprises an n-region which is an n-type doped region grown on the buffer layer; an active layer which is grown on the n-region and emits ultraviolet rays by recombination of electrons and holes; and a p-region which is a p-type doped region grown on the active layer; and the first fab process step comprises a channel process which forms a channel layer around an upper surface of the p-region; a p-ohmic process which forms the p-ohmic layer in an area of the upper surface of the p-region excluding the channel layer; and the seed region removal step removes the seed region and the buffer layer to expose the n-region, and a crystal plane of the exposed n-region is a nitrogen (N) polarity plane.

In embodiments according to the present invention, the second fab process step comprises an isolation process for mesa-etching a periphery of the light-emitting layer so as to expose the channel layer; a passivation process for forming a passivation layer for protecting a surface exposed by the isolation process; a texture process for forming a roughness pattern for light extraction on an upper surface of the n-region exposed by the seed region removal step; and an electrode process for forming the electrode for supplying current to the n-region and the p-region.

In embodiments according to the present invention, the light-emitting layer comprises an n-region which is an n-type doped region grown on the buffer layer; an active layer which is grown on the n-region and emits ultraviolet rays by recombination of electrons and holes; and a p-region which is a p-type doped region grown on the active layer; and the first fab process step comprises a channel process which forms a channel layer along a perimeter of an upper surface of the p-region; a via-hole process which forms a via hole so that the n-region is exposed from an upper surface of the p-region through the active layer; a p-ohmic process which forms the p-ohmic layer in ohmic contact with the p-region; an insulation process which electrically insulates the n-region exposed by the via-hole process from the p-region and the p-ohmic layer, and an n-ohmic process for forming an n-ohmic layer in ohmic contact with the n-region exposed by the via hole process;, and wherein the seed region removal step removes only the seed region to leave the buffer layer, and the crystal plane of the n-region facing the buffer layer is a group 3 metal (Al, Ga) polarity plane.

In embodiments according to the present invention, the second fab process step comprises an isolation process for mesa-etching the periphery of the light-emitting layer and the buffer layer so that the channel layer is exposed; a passivation process for forming a passivation layer for protecting a surface exposed by the isolation process; a texture process for forming a roughness pattern for light extraction on the exposed surface of the buffer layer; and an electrode process for forming the electrode for supplying current to the n-region and the p-region.

In embodiments according to the present invention, the support substrate is formed of a material having electrical conductivity, and the second fab process step comprises forming an electrode provided on an exposed bottom surface of the support substrate and electrically connected to one of the n-ohmic layer and the p-ohmic layer via the support substrate.

In embodiments according to the present invention, the support substrate is made of a non-conductive material, and the second fab process step forms an electrode that is electrically connected to the n-ohmic layer and/or the p-ohmic layer formed in the first fab process step.

### Advantageous Effects

Embodiments according to the present invention have the advantage of drastically reducing the manufacturing cost of deep ultraviolet light-emitting devices using group III nitrides by making it possible to thin a SiC growth substrate for deep ultraviolet light-emitting devices using group III nitrides as a material using a hot self-split technique utilizing stealth laser technology.

Embodiments according to the present invention have the advantage of greatly improving the uniformity within the wafer and greatly reducing the defect rate due to breakage, including wafer cracking, in forming a deep ultraviolet light-emitting device using a group III nitride as a material on a thinned SiC growth substrate by applying a process in which a wafer bonding process is further integrated.

### BRIEF DESCRIPTION OF DRAWINGS

FIGS. 1, 2, 3, 4, 5, 6, 7, 8 and 9 are drawings for explaining one embodiment according to the present invention.

FIGS. 10, 11, 12, 13, 14, 15, 16, 17 and 18 are drawings for explaining another embodiment according to the present invention.

FIG. 19 is a drawing showing the flow of a method for manufacturing a high-power ultraviolet light emitting device of a thin film type chip structure through a hot self-split process according to the present invention.

### DETAILED DESCRIPTION

Hereinafter, a method for manufacturing a high-power ultraviolet light emitting device of a thin film type chip structure through a hot self-split process according to embodiments of the present invention will be described in detail with reference to the drawings.

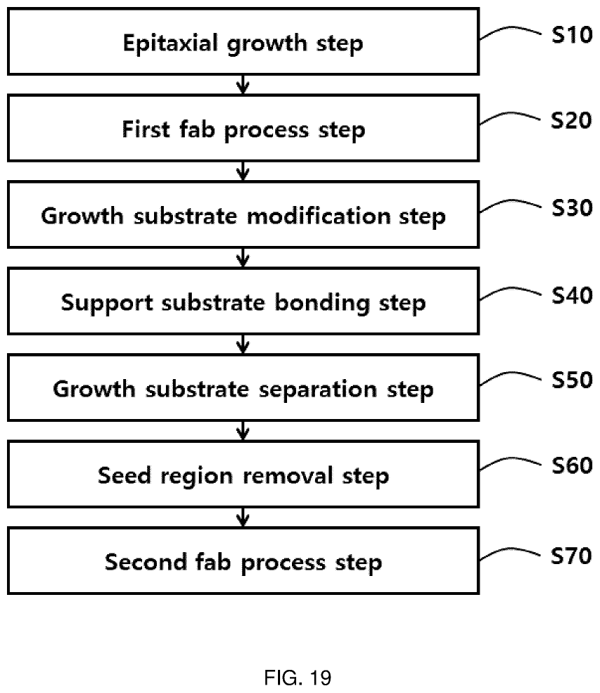

The terms used below have been selected for convenience of explanation, and should be appropriately interpreted in a meaning that is consistent with the technical idea of the present invention without being limited to the dictionary meaning. Referring to FIG. 19, embodiments according to the present invention comprise an epitaxial growth step (S10), a first fab process step (S20), a growth substrate modification step (S30), a support substrate bonding step (S40), a growth substrate separation step (S50), a seed region removal step (S60), and a second fab process step (S70).

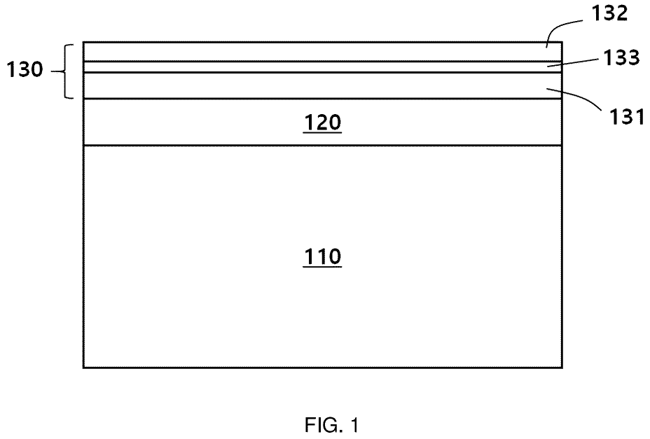

FIG. 1 is for explaining the epitaxial growth step (S10).

The epitaxial growth step (S10) is a step of sequentially forming a buffer layer (120) and a light-emitting layer (130) on a growth substrate (110) made of SiC (silicon carbide).

The buffer layer (120) and the light-emitting layer (130) are formed of group III nitride (AlN, AlGaN, GaN). They may be composed of AlN and Al-rich AlₓGa₁₋ₓN (x>0.5).

The light-emitting layer (130) is composed of an n-region (131), which is an n-type doping region, an active layer (133) that is grown on the n-region (131) and emits ultraviolet rays by recombination of electrons and holes, and a p-region (132), which is a p-type doping region.

The buffer layer (120) and the light-emitting layer (130) may be provided with multiple layers having different materials or growth conditions. The growth substrate (110) provided with SiC (silicon carbide) is preferably provided with 4H-SiC having a growth surface with Si polarity (Si-polar). 6H-SiC is not excluded.

The Si-polar 4H-SiC growth substrate can minimize misfit dislocations by having a lattice constant difference of 0.9% with the buffer layer material mainly using AlN (aluminum nitride).

In addition, the density of threading dislocations, which are crystal defects, can be reduced during the growth of the light-emitting layer (130) formed as a subsequent process.

In addition, the overall thickness can be minimized compared to when growing on a sapphire growth substrate. This is based on the fact that AlN (aluminum nitride), which is a buffer layer (120) for a high-quality light-emitting layer (130), is sufficient with a thickness of about 2 μm.

The embodiments according to the present invention feature a manufacturing method that uses an expensive SiC growth substrate to manufacture a high-quality and high-output deep ultraviolet light-emitting device while using an expensive SiC growth substrate at a high cost-effectiveness.

Next, the first fab process step (S20) is a step of forming an n-ohmic layer (152) and/or a p-ohmic layer (151) on the light-emitting layer (130).

It is preferable that a channel layer (140) is formed on the upper surface of the p-region (132) prior to the formation of the n-ohmic layer (152) and/or the p-ohmic layer (151).

The channel layer (140) prevents interlayer short-circuiting of the light-emitting layer (130) even when the light-emitting layer (130) is exposed to moisture.

In addition, the channel layer (140) is beneficial in strengthening the sealing during the passivation process and the dry etch damage during the isolation process in the subsequent second fab process step (S70).

The channel layer (140) is formed around the upper surface of the p-region (132) and is formed in a closed loop shape.

It can be formed in a loop shape, a ring shape, or a frame shape.

The channel layer (140) can be selected from materials such as oxide and nitride, and can be selectively formed from ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), SiO₂, SiOₓ, SiOₓN_{y}, Si₃N₄, Al₂O₃, TiO₂, etc.

The meaning of the n-ohmic layer (152) and/or the p-ohmic layer (151)′ means that only the p-ohmic layer (151) is formed, and both the n-ohmic layer (152) and the p-ohmic layer (151) are formed.

These are distinguished according to the polarity of the crystal plane of the surface that contacts the buffer layer (120) among the two sides of the n-region (131).

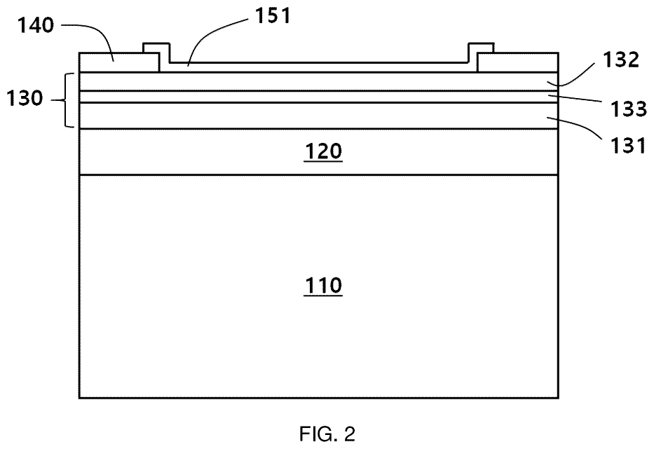

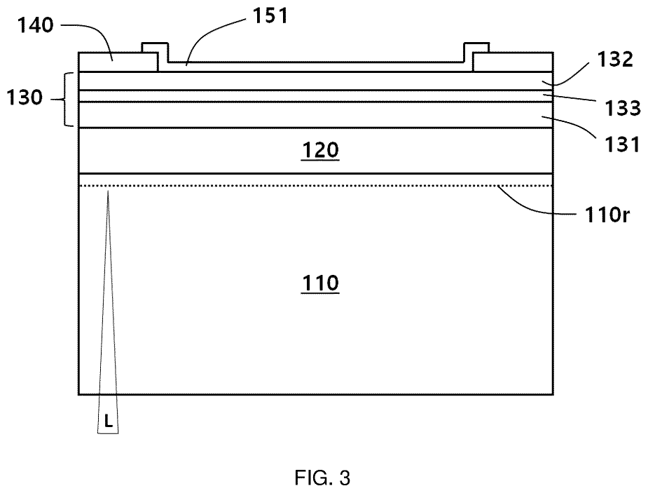

When the crystal plane is nitrogen (N) polarized, only the p-ohmic layer (151) is formed, as in FIG. 2, and the subsequent process is as in FIGS. 3 to 9.

When the crystal plane is group 3 metal (Al, Ga) polarized, both the n-ohmic layer (152) and the p-ohmic layer (151) are formed.

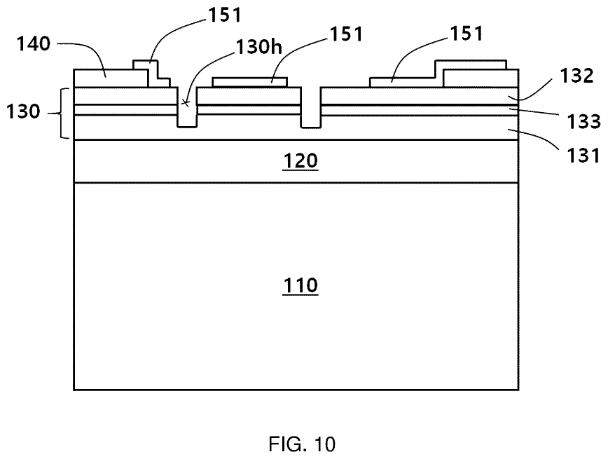

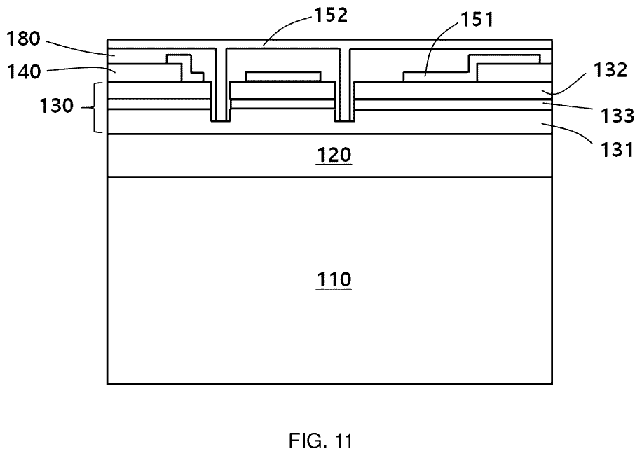

At this time, the n-ohmic layer (152) is located at the top layer. This is as shown in FIG. 10, and the subsequent processes are as shown in FIGS. 11 to 18. First, the process according to FIGS. 2 to 9 will be described.

Referring to FIG. 2, the first fab process step (S20) forms a channel layer (140) around the upper surface of the p-region (132), and forms a p-ohmic layer (151) in the area of the upper surface of the p-region (132) excluding the channel layer (140).

A reflective layer may be introduced together with the p-ohmic layer (151).

The p-ohmic layer (151) may be formed over the entire upper surface of the p-region, and may be formed to surround the inner end of the channel layer (140).

The ohmic layer can be formed by selectively using a conductive oxide or metal, and can be formed as a single layer or multilayer using one or more of ITO (indium tin oxide), IZO (indium zinc oxide), IZTO (indium zinc tin oxide), IAZO (indium aluminum zinc oxide), IGZO (indium gallium zinc oxide), IGTO (indium gallium tin oxide), AZO (aluminum zinc oxide), ATO (antimony tin oxide), GZO (gallium zinc oxide), IrOx, RuOx, RuOx/ITO, Ni, Ag, Rh, AI, ITO/Ag, ITO/AI, Ni/IrOx/Au, and Ni/IrOx/Au/ITO.

FIGS. 3 to 5 specifically show a method of using an expensive SiC growth substrate at a high cost-effectiveness, and are related to a growth substrate modification step (S30), a support substrate bonding step (S40), and a growth substrate separation step (S50).

The growth substrate modification step (S30) forms a modified layer (110r) parallel to the growth surface of the growth substrate (110) by irradiating a laser (L) inside the growth substrate (110).

The laser (L) uses a stealth laser that can form a focal point at a specific point inside the growth substrate (110).

The focal point of the laser (L) causes photons to be locally concentrated in a microspace, resulting in a nonlinear energy absorption phenomenon.

By this, the bonding between the constituent elements of the growth substrate (110) at the focal position is destroyed, and when the focal point is moved along a specific plane to form a scanning plane, a modified layer (110r) is formed along the scanning plane.

At this time, the scanning method is formed by performing the scanning in the left-right direction in the form of a line, or by rotating 90° in the form of a lattice.

The support substrate bonding step (S40) bonds the support substrate (160) to either the n-ohmic layer (152) or the p-ohmic layer (151) formed by the first fab process.

Here, the bonding of the p-ohmic layer (151) and the support substrate (160) is described, and the bonding of the n-ohmic layer (152) and the support substrate (160) is described later with reference to FIGS. 10 to 17.

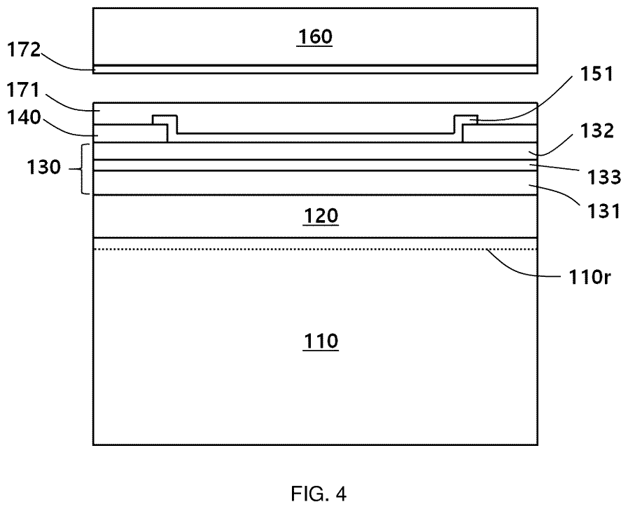

Referring to FIG. 4, first, a device bonding layer (171) is formed on one side of the light-emitting layer (130) on which the channel layer (140) and the p-ohmic layer (151) are formed using a bonding material.

The device bonding layer (171) is formed so as to cover both the channel layer (140) and the p-ohmic layer (151).

In addition, a substrate bonding layer (172) is formed on the support substrate (160) using the same bonding material as the device bonding layer (171).

It is preferable that the bonding material is provided with a material having electrical conductivity. In addition, the bonding material is preferably a material having excellent heat dissipation characteristics for the operational stability of the high-power deep ultraviolet light-emitting device.

Next, the device bonding layer (171) and the substrate bonding layer (172) are bonded to form a bonding layer (170).

The conductive bonding is preferably a metal bonding. Metal bonding may include direct high-temperature bonding, diffusion bonding, and eutectic bonding as examples.

The bonding layer (170) may include a diffusion blocking layer to prevent the materials of the light-emitting layer (130) and the support substrate (160) from diffusing during the process of bonding the light-emitting layer (130) and the support substrate (160).

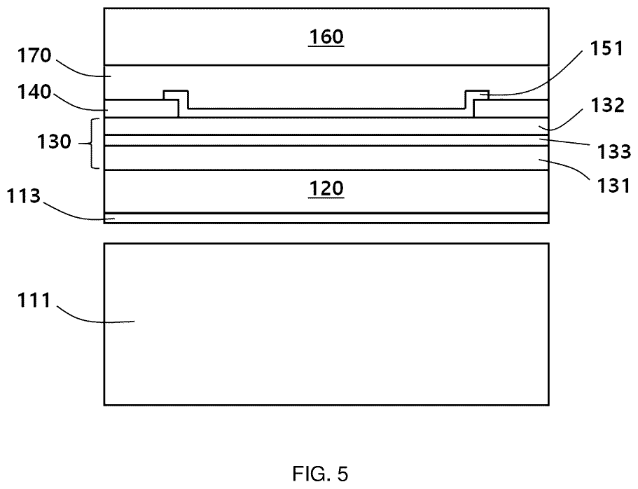

Referring to FIG. 5, the growth substrate separation step (S50) is a step in which the growth substrate (110) is separated with the modified layer (110r) as the boundary, and the seed region (113), which is part of the growth substrate (110), remains on the light-emitting layer (130).

Here, the separation of the growth substrate (110) with the modified layer (110r) as the boundary has the characteristic of being separated without an external force for the purpose of separation.

Since the application of a mechanical external force for separation is unnecessary, the thickness of the seed region (113) can be minimized, and as a result, the cost-effectiveness of the expensive SiC growth substrate is increased.

The separation of the growth substrate (110) with the modified layer (110r) as the boundary is achieved by a quantitative difference in thermal characteristics including the thermal expansion rate of both sides of the growth substrate (110) centered on the modified layer (110r) or a structural asymmetry including a thickness difference.

Structural asymmetry refers to the difference in material and thickness between the light-emitting layer (130) and the growth substrate (110) with the modified layer (110r) as the boundary, and the thermal stress or mechanical stress formed in the modified layer (110r) enables separation without external force.

The thermal or mechanical stress is generated as a result of the wafer bonding process in which heat is transferred only to one side with the modified layer (110r) as the boundary.

Meanwhile, the growth substrate (111) separated from the light-emitting layer (130) by the growth substrate separation step (S50) is reused for the growth of a new buffer layer and light-emitting layer.

This increases the cost-effectiveness of the expensive SiC growth substrate.

At this time, prior to the growth of a new buffer layer and light-emitting layer on the separated growth substrate (111), a mechanical or/and chemical-mechanical polishing (MP, CMP) process may be included to make the surface smooth like a mirror.

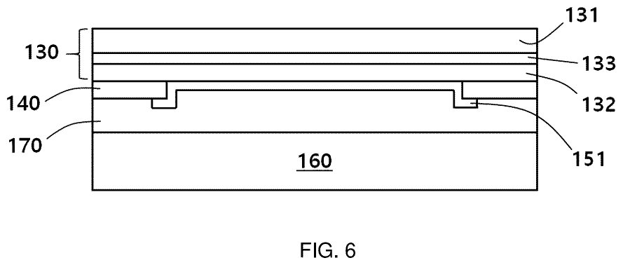

FIG. 6 is a drawing showing a state where the seed region (113) and the buffer layer (120) are removed and the vertical direction is reversed.

The seed region removal step (S60) can be divided into a case where the seed region (113) and the buffer layer (120) are removed together to expose the n-region (131) of the light-emitting layer (130), and a case where only the seed region (113) is removed to expose the buffer layer (120).

This is divided according to the polarity of the crystal plane of the surface of the n-region (131) that comes into contact with the buffer layer (120).

If the crystal plane has a nitrogen (N) polarity, it is possible to form an electrode that makes an ohmic contact with the n-region (131), so the seed region (113) and the buffer layer (120) are removed together to expose the n-region (131) of the light-emitting layer (130).

In the case where the crystal plane is a group 3 metal (Al, Ga) polarity, an ohmic contact through the n-ohmic layer (152) is required, so only the seed region (113) is removed to expose the buffer layer (120). This will be described later.

The removal of the seed region (113) and/or the buffer layer (120) is preferably done by chemical etching. The chemical etching refers to a wet and/or dry process.

Next, the second fab process step (S70) is a step of forming a device structure including electrodes (151a, 152a) for supplying current to the light-emitting layer (130).

It includes an isolation process, a texture process, a passivation process, and an electrode process.

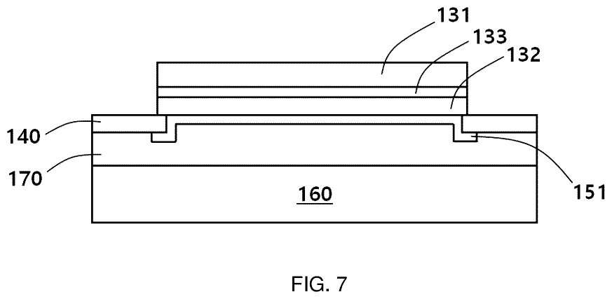

It will be described with reference to FIGS. 7 to 9.

The isolation process is a process of mesa-etching the perimeter of the light-emitting layer (130).

The chip-to-chip boundary area is removed by isolation etching.

The channel layer (140) can be etched to an extent that it is exposed by the isolation process.

The side surface of the light-emitting layer (130) can be formed to be inclined by the isolation process.

The texture process is a process of forming a roughness pattern by etching the upper surface of the n-region (131) exposed by the seed region removal step (S60).

The roughness pattern improves the light extraction efficiency.

The passivation process is a process of forming a protective layer (190) that protects the surface exposed by the isolation process.

The protective layer (190) is formed around the chip including the light-emitting layer (130), the lower part is formed on the channel layer (140), and the upper part is formed around the upper surface of the light-emitting layer (130).

The protective layer (190) prevents a short circuit from occurring between the layers (131, 132, 133) constituting the light-emitting layer (130). In addition, the protective layer (190) and the channel layer (140) can prevent moisture from penetrating into the chip.

The electrode process is a process of forming electrodes (151a, 152a) for supplying current to the n-region (131) and the p-region (132).

The electrodes (151a, 152a) are formed as an n-side electrode (152a) electrically connected to the n-region (131) and a p-side electrode (151a) electrically connected to the p-region (132).

The n-side electrode (152a) and the p-side electrode (151a) may include a reflective layer to improve light extraction efficiency.

The n-side electrode (152a) is formed as an electrode pad on the upper surface of the n-region (131).

The p-side electrode (151a) has a different shape depending on whether the support substrate (160) has electrical conductivity.

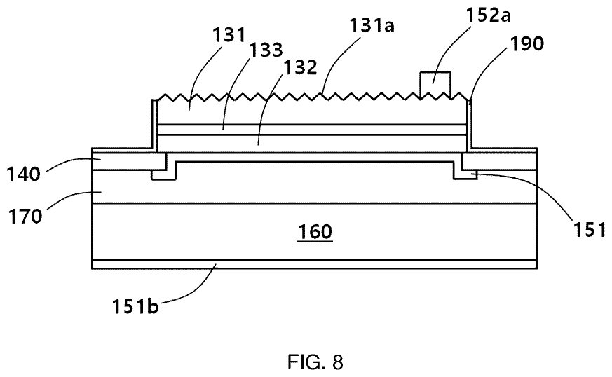

FIG. 8 shows a case where the support substrate (160) has electrical conductivity, and the p-side electrode (151a) is formed as a p-side electrode layer (151b) on the bottom surface of the support substrate (160).

In order to form the p-side electrode layer (151b), lapping and polishing may be performed on the bottom surface of the support substrate (160). Examples of the support substrate (160) having electrical conductivity include n-type SiC, MoCu, and CuW.

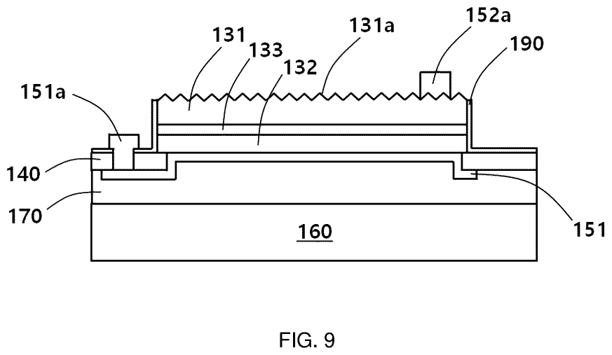

FIG. 9 shows a case where the support substrate (160) does not have electrical conductivity, and the p-side electrode (151a) is formed as an electrode pad connected to the p-ohmic layer (151).

Examples of the support substrate (160) not having electrical conductivity include Semi Insulating SiC and AlN_{cera}.

Next, another embodiment according to the present invention will be described with reference to FIGS. 10 to 18.

This embodiment includes, as in the previously described embodiment, an epitaxial growth step (S10), a first fab process step (S20), a growth substrate modification step (S30), a support substrate bonding step (S40), a growth substrate separation step (S50), a seed region removal step (S60), and a second fab process step (S70).

However, this embodiment is for the case where the polarity of the crystal plane of the surface of the n-region (131) constituting the light-emitting layer (130) that comes into contact with the buffer layer (120) is a group 3 metal (Al, Ga) polarity.

Accordingly, there is a difference from the previously described embodiment in the first fab process step (S20), the support substrate bonding step (S40), the seed region removal step (S60), and the second fab process step (S70).

The first fab process step (S20) includes a channel process, a via hole process, a p-ohmic process, an insulation process, and an n-ohmic process.

Referring to FIGS. 10 and 11, the channel process forms a channel layer (140) along the upper surface perimeter of the p-region (132).

The via hole process forms a via hole (130h) so that the n-region is exposed from the upper surface of the p-region (132) through the active layer (133).

The p-ohmic process forms a p-ohmic layer (151) that makes an ohmic contact with the p-region (132).

The insulation process electrically insulates the n-region (131) exposed by the via hole process from the p-region (132) and the p-ohmic layer (151).

An insulation layer (180) is formed on the upper surface of the p-region (132) and the p-ohmic layer (151) and the upper surface of the channel layer, excluding the bottom surface of the via hole (130h) formed by the via hole process.

The n-ohmic process forms an n-ohmic layer (152) that makes ohmic contact with the n-region (131) exposed by the via hole process.

The n-ohmic layer (152) makes ohmic contact with the n-region (131) via the via hole (130h) and is formed on the entire upper surface of the light-emitting layer (130).

The n-ohmic layer (152) is partitioned from the p-region (132), the p-ohmic layer (151), and the channel layer (140) by the insulating layer (180).

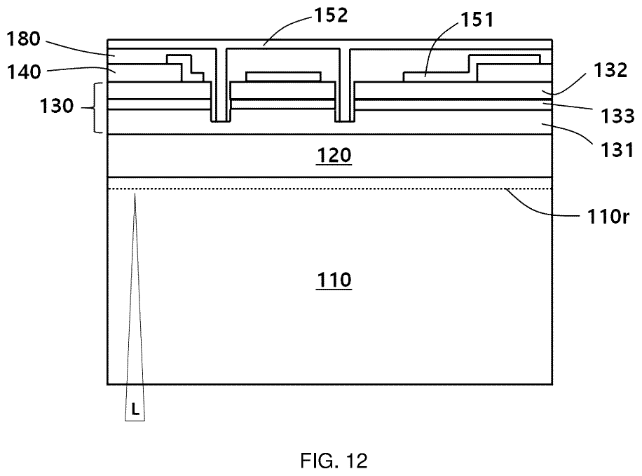

FIG. 12 is about a growth substrate modification step (S30) for forming a modification layer (110r) on a growth substrate (110), which is the same as the growth substrate modification step (S30) of the previously described embodiment.

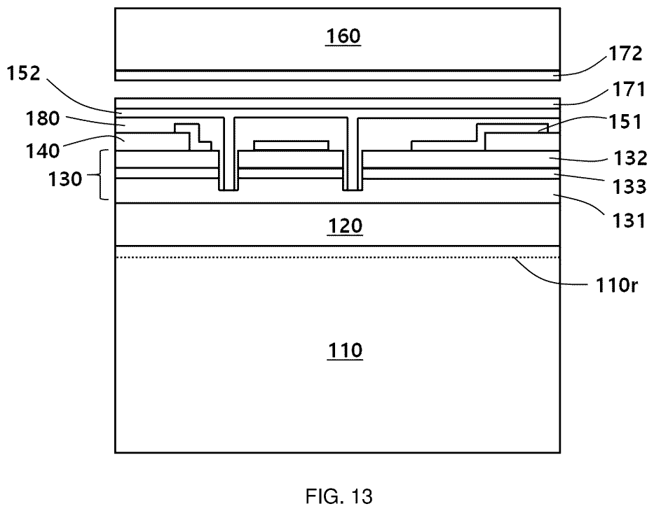

FIG. 13 is about a support substrate bonding step (S40), and unlike the previously described embodiment, the n-ohmic layer (152) is bonded while facing the support substrate (160).

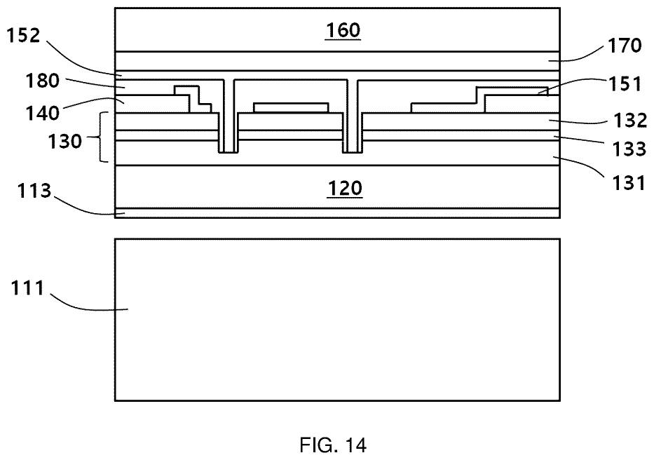

FIG. 14 is about a growth substrate separation step (S50), and is the same as the growth substrate separation step (S50) of the previously described embodiment.

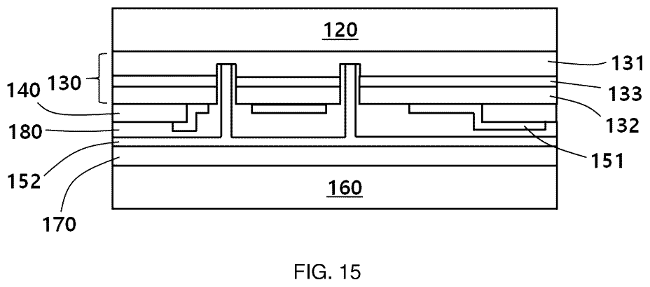

FIG. 15 is about a seed region removal step (S60), and unlike the previously described embodiment, only the seed region (113) is removed, and the buffer layer (120) is maintained.

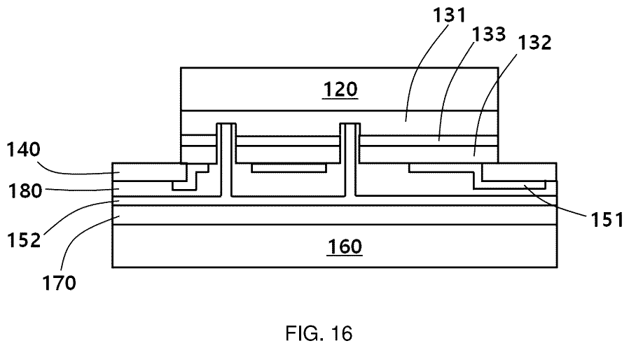

FIGS. 16 to 18 relate to the second fab process step (S70), which includes an isolation process, a texture process, a passivation process, and an electrode process, as in the previously described embodiment.

The isolation process is a process of mesa-etching the perimeter of the light-emitting layer (130) and the buffer layer (120).

The chip-to-chip boundary area is removed by isolation etching. The isolation process can be etched to the extent that the channel layer (140) is exposed.

The texture process is a process of etching the upper surface of the n-region (131) exposed by the seed region removal step (S60) to form a roughness pattern.

The roughness pattern improves light extraction efficiency.

The passivation process is a process of forming a protective layer (190) that protects the surface exposed by the isolation process.

The protective layer (190) is formed around the chip including the light-emitting layer (130) and the buffer layer (120), and the lower part is formed on the channel layer (140), and the upper part is formed around the upper surface of the buffer layer (120).

The protective layer (190) can prevent a short circuit that may occur between the layers (131, 132, 133) that constitute the light-emitting layer (130). In addition, the protective layer (190) and the channel layer (140) can prevent moisture from penetrating into the chip.

The electrode process is a process of forming electrodes (151a, 152a) for supplying current to the n-region (131) and the p-region (132). Electrodes (151a, 152a) are formed as an n-side electrode (152a) electrically connected to the n-region (131), and a p-side electrode (151a) electrically connected to the p-region (132).

The n-side electrode (152a) and the p-side electrode (151a) may include a reflective layer to improve light extraction efficiency.

The p-side electrode (151a) is formed as an electrode pad that penetrates the protective layer (190) and the channel layer (140) and connects to the p-ohmic layer (151).

The n-side electrode (152a) has a different shape depending on whether the supporting substrate (160) has electrical conductivity.

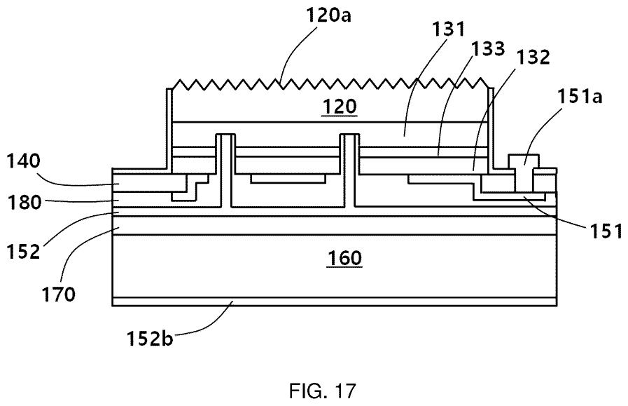

FIG. 17 shows a case where the supporting substrate (160) has electrical conductivity, and the n-side electrode (152a) is formed as an n-side electrode layer (152b) on the bottom surface of the supporting substrate (160).

In order to form the n-side electrode layer (152b), lapping and polishing may be performed on the bottom surface of the support substrate (160).

Examples of the support substrate (160) having electrical conductivity include n-type SiC, MoCu, and CuW.

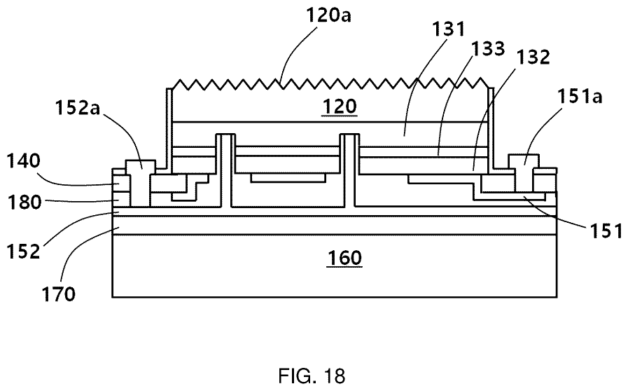

FIG. 18 shows a case where the support substrate (160) does not have electrical conductivity, and the n-side electrode (152a) is formed as an electrode pad that penetrates the protective layer (190), the channel layer (140), and the insulating layer (180) and is connected to the n-ohmic layer (152).

Examples of the support substrate (160) not having electrical conductivity include Semi-Insulating SiC and AINcera.

As described above, the embodiments according to the present invention have a structural feature that allows selection of a crystal plane for ohmic contact, and thus can greatly contribute to securing excellent electrical characteristics of a high-power deep ultraviolet light-emitting device having a thin film chip structure.

In addition, the embodiments according to the present invention can have high-quality film formation quality because the light-emitting layer (130) is epitaxially grown on a thick growth substrate (110), and the quality uniformity on the entire surface of the light-emitting layer (130) is also very high.

In addition, the embodiments according to the present invention can separate the light-emitting layer (130) and the device structure having high-quality film formation quality without damage by the support substrate bonding and hot self-split process.

The support substrate (160) ensures stable performance of the subsequent secondary fab process.

What is claimed is:

1. A method for manufacturing a high-power ultraviolet light-emitting device having a thin-film chip structure through a hot self-split process comprising:
an epitaxial growth step of sequentially forming a buffer layer and an emission layer on a growth substrate made of SiC (silicon carbide);
a first fab process step of forming an n-ohmic layer and/or a p-ohmic layer on the emission layer;
a growth substrate modification step of irradiating a laser into the inside of the growth substrate to form a modified layer parallel to a growth surface of the growth substrate;
a support substrate bonding step of bonding a support substrate to one of the n-ohmic layer and the p-ohmic layer formed by the first fabrication process;
a growth substrate separation step of separating the growth substrate with the modified layer as a boundary, and leaving a seed region, which is a part of the growth substrate, in the emission layer;
a seed region removal step of removing the seed region and the buffer layer together to expose the emission layer, or removing only the seed region to expose the buffer layer; and
a second fab process step of forming a device structure including an electrode electrically connected to the light-emitting layer.

2. The method of claim 1, wherein the growth substrate separation step is performed such that the growth substrate is separated with the modified layer as a boundary due to thermal stress or mechanical stress formed in the modified layer as a result of the support substrate bonding.

3. The method of claim 1, wherein the growth substrate separated from the light-emitting layer by the growth substrate separation step is reused for the growth of a new buffer layer and light-emitting layer.

4. The method of claim 1, wherein the support substrate bonding step bonds an electrically conductive device bonding layer formed on one surface of the light-emitting layer and an electrically conductive substrate bonding layer formed on the support substrate.

5. The method of claim 4, wherein the light-emitting layer comprises an n-region which is an n-type doped region grown on the buffer layer; an active layer which is grown on the n-region and emits ultraviolet rays by recombination of electrons and holes; and a p-region which is a p-type doped region grown on the active layer; and
the first fab process step comprises a channel process which forms a channel layer around an upper surface of the p-region; and a p-ohmic process which forms the p-ohmic layer in an area of the upper surface of the p-region excluding the channel layer; and
the seed region removal step removes the seed region and the buffer layer to expose the n-region, and a crystal plane of the exposed n-region is a nitrogen (N) polarity plane.

6. The method of claim 5, wherein the second fab process step comprises an isolation process for mesa-etching a periphery of the light-emitting layer so as to expose the channel layer; a passivation process for forming a passivation layer for protecting a surface exposed by the isolation process; a texture process for forming a roughness pattern for light extraction on an upper surface of the n-region exposed by the seed region removal step; and an electrode process for forming the electrode for supplying current to the n-region and the p-region.

7. The method of claim 4, wherein the light-emitting layer comprises an n-region which is an n-type doped region grown on the buffer layer; an active layer which is grown on the n-region and emits ultraviolet rays by recombination of electrons and holes; and a p-region which is a p-type doped region grown on the active layer; and
the first fab process step comprises a channel process which forms a channel layer along a perimeter of an upper surface of the p-region; a via-hole process which forms a via hole so that the n-region is exposed from an upper surface of the p-region through the active layer; a p-ohmic process which forms the p-ohmic layer in ohmic contact with the p-region; an insulation process which electrically insulates the n-region exposed by the via-hole process from the p-region and the p-ohmic layer, and an n-ohmic process for forming an n-ohmic layer in ohmic contact with the n-region exposed by the via hole process;, and
wherein the seed region removal step removes only the seed region to leave the buffer layer, and the crystal plane of the n-region facing the buffer layer is a group 3 metal (Al, Ga) polarity plane.

8. The method of claim 7, wherein the second fab process step comprises an isolation process for mesa-etching the periphery of the light-emitting layer and the buffer layer so that the channel layer is exposed; a passivation process for forming a passivation layer for protecting a surface exposed by the isolation process; a texture process for forming a roughness pattern for light extraction on the exposed surface of the buffer layer; and an electrode process for forming the electrode for supplying current to the n-region and the p-region.

9. The method of claim 8, wherein the support substrate is formed of a material having electrical conductivity, and the second fab process step comprises forming an electrode provided on an exposed bottom surface of the support substrate and electrically connected to one of the n-ohmic layer and the p-ohmic layer via the support substrate.

10. The method of claim 8, wherein the support substrate is made of a non-conductive material, and the second fab process step forms an electrode that is electrically connected to the n-ohmic layer and/or the p-ohmic layer formed in the first fab process step.
